(19) United States
(12) Patent Application Publication
(10) Pub. No.: US 2007/0111494 A1
(43) Pub. Date: May 17, 2007

(54) Handling of flexible planar material

(75) Inventors: David Stephen Thomas, Cambridge (GB); Philip Gareth Bentley, Cambridge (GB)

Correspondence Address: MORGAN LEWIS & BOCKIUS LLP, 1111 PENNSYLVANIA AVENUE NW, WASHINGTON, DC, 20004, US

(73) Assignee: Conductive Inkjet Technology Limited

(21) Appl. No.: 11/598,066

(22) Filed: Nov. 13, 2006

Related U.S. Application Data
(60) Provisional application No. 60/735,860, filed on Nov. 14, 2005.

(30) Foreign Application Priority Data
Nov. 11, 2005 (GB) 0523013.1

(51) Int. Cl. H01L 21/44

(52) U.S. Cl. 438/597

(57) ABSTRACT

A method of handling a length of flexible planar material, comprises conveying the material (1) past a first contacting point (2), and applying a flow of fluid (6) to the material thereby applying a drag force on the material which induces a tensile force in the material with respect to the contacting point. Apparatus for performing the method is also disclosed.

### FIELD OF THE INVENTION

This invention relates to the handling of flexible planar material, with particular application in continuous processing of a web of flexible material such as in the deposition of an electrically conducting layer on a moving web of material such as polyester.

### BACKGROUND OF THE INVENTION

In order to perform chemical reactions on a moving web of material (for example electro-less deposition of copper onto an activated catalytic material or for the developing of photographic images), the web has traditionally been sequentially immersed in a series of baths of liquids. As a practical necessity for these processes, the web has been wound around a series of rollers in order to control its path through the baths, and in some cases the web is wound in a serpentine path around these rollers in order to prolong its time in a particular bath. When a moving web is immersed in a bath of liquid in order to effect a chemical reaction, the time allowed for such a reaction to take place is governed by the speed at which the web travels and the total length of path which the web takes through the liquid bath. The more tortuous the path, the longer the web spends in the liquid for a given speed of web translation. Traditionally, the web is kept in tension and guided along its path by winding it around a series of rollers disposed in the liquid.

WO 2006/100467 discloses arrangements in which a flexible web passes through a fluid not under tension. The web is not constrained by tensioning means, nor typically by path-defining guides, within the fluid. The web may instead be constrained by one or more walls confining the fluid, typically walls of a fluid container.

Because the arrangements are tensionless, the webs are prone to buckling or folding.

### SUMMARY OF THE INVENTION

According to a first aspect of the invention, there is provided a method of handling a length of flexible planar material, comprising conveying the material past a first contacting point, and applying a flow of fluid to the material thereby applying a drag force on the material which induces a tensile force in the material with respect to the contacting point.

Thus, the fluid applies a small amount of controlled tension by applying a drag force on the ribbon in order to ensure it enters and/or leaves the contacting point without buckling or sticking.

Another aspect of the invention provides apparatus for handling a length of flexible planar material, comprising a first contacting point, means for conveying the material past the first contacting point, and means for applying a flow of fluid to the material such that, in use, fluid applied to the ribbon applies a drag force on the material which induces a tensile force in the material with respect to the contacting point.

Contacting Point

The first contacting point is typically a roller, rotating arm or cantilevered roller, and is preferably a pair of rollers, at least one of which is driven.

Optionally a second contacting point is provided, with the material moving along its length on a path from the first to the second contacting point. The path taken by the material may be direct or tortuous, depending on the intended use. The second contacting point may be a roller etc. as discussed in connection with the first contacting point. The second contacting point may alternatively be wiper means e.g. in the form of one or more wiper blades, possibly in the form of a squeegee.

The first contacting point is typically upstream of the application of fluid, but may be downstream.

Fluid

The fluid may be liquid, gas, plasma, or mixtures thereof, possibly with entrained particles, e.g. sand or glass beads. Preferably the fluid is a liquid.

The fluid is applied by directing a flow of fluid onto the material. The contact of the fluid with the material causes a natural drag force on the ribbon which causes a controlled tension in the material with respect to the first contacting point. The drag force can originate from the momentum transferred from the fluid on impact with the material (i.e. impact force) and/or from gravitational force due to the weight of the fluid on the material (especially when the fluid is a liquid). Thus the fluid may be directed to impact the material with a velocity having a component directed away from the contacting point.

Preferably the fluid impinges on the material with a component of motion parallel to the direction of travel of the material. This may be achieved as a result of the direction of application of fluid, possibly in combination with the effect of gravity. Preferably the fluid is directed at the material with a component of motion parallel to the direction of travel of the material.

The direction of travel of the material may be vertical, horizontal or inclined.

The fluid may be applied to both sides of the material or only to a single side. Fluid will generally be applied to both sides for reasons of stability. However, in some cases fluid can be directed onto a single side e.g. when the material is travelling along a substantially horizontal path and fluid may be applied from the underside only. In this case gravity acts on the material to balance any impact momentum applied to the material from the fluid contact side. Fluid may also be applied to a single side of a material in a substantially vertical arrangement, for example when a liquid is applied without substantial impact momentum, the drag force then being generated by gravity acting on the liquid in contact with the material.

The fluid is conveniently applied in a plurality of channels or jets, typically arranged in a regular array, e.g. from a manifold or array of manifolds. Typically the material passes past at least one guide. Advantageously the fluid passes over or through a channel in the guide which is then acting as a fluid guide. A preferred arrangement uses a pair of opposed manifold assemblies constituting fluid guides and defining therebetween an elongate slot or gap through which the material passes. The slot or gap is conveniently tapered, being narrower at the end remote from the first contact point.

Flexible Planar Material

The flexible planar material is typically in the form of an elongate strip or ribbon. The material is preferably in the form of a web of flexible material, for conveying around rollers. A non-exhaustive list of suitable materials includes, for example, plastics materials e.g. Melinex polythylene terephthalate (PET) (Melinex is a trade mark), paper, metal foils and fabrics.

Applications

The invention is particularly advantageous in circumstances in which the flexible material, in the region where fluid is applied, is in a tensionless condition other than tension resulting from the fluid. For example, where the first contacting point is upstream of the application of fluid, then the material downstream of the application of fluid may be in tensionless condition, e.g. passing in tensionless condition through a fluid bath as disclosed in WO 2006/100467.

The invention finds particular application in the handling of material for continuous processing including immersion in a fluid bath. The fluid applied to the material is preferably the same fluid as the bath contents, with the fluid being circulated as appropriate. The bath may be generally as disclosed in the specification of WO 2006/100467, with the material in tensionless condition, not being constrained by tensioning means in the bath.

When a bath of fluid is used the path followed by the material within the liquid may be in the general shape of a catenary or parabolic loop, but in circumstances where it is desirable for the material to follow a longer path within the fluid the path may be of a sinuous or serpentine shape, having a plurality of superposed folds from the lowest of which the material moves generally upwardly through the liquid before being withdrawn therefrom.

Immersion of the material in the fluid may be for any purpose, but preferably a chemical reaction takes place between the material and the fluid. For example, electrically conductive metal layers may be formed on the material by processes such as electroless deposition, with the material being passed through one or more fluid baths. Other possibilities include photographic development, etching, dissolution, stripping, etc. The fluid may also be constituted by a controlled environment within a container, e.g. a gaseous environment having specified characteristics, e.g. humidity, temperature etc.

In a preferred embodiment, an electrically conductive metal layer, e.g. of copper, is formed on a length of flexible planar material, e.g. of polyester, in a continuous process by conveying the material continuously through various processing stages. In a first stage an activator such as a catalyst or catalyst precursor, e.g. palladium acetate, is deposited on the material, possibly in patternwise manner, by inkjet printing. After optional curing, e.g. by exposure to ultraviolet (UV) to adhere the activator to the material, the material is passed through a bath as disclosed in WO 2006/100467 containing a solution of reducing agent preferably dimethylamineborane (DMAB) to reduce the palladium acetate to palladium which is catalytically active, with the material not under tension. The material is conveyed to the bath by the method of the invention, using DMAB solution as the applied fluid. After optional washing in water, the material is passed through a further bath of similar construction to the DMAB bath and containing an electroless copper plating solution, e.g. comprising Enplate A, B and C reagents (Enplate is a Trade Mark) available from Enthone-OM1. The Enplate solution is used as the applied fluid. After a further optional wash in water the material is collected. Parameters including the speed of movement of the material and length of material in each bath are selected appropriately to provide suitable residence times in the baths for desired reaction.

### BRIEF DESCRIPTION OF THE FIGURES

The invention will now be illustrated with reference to the following figures, in which:

FIG. 1 is a schematic sectional view of one embodiment of apparatus according to the invention;

FIG. 2 is a schematic sectional view of another embodiment of apparatus according to the invention;

FIG. 3 is a schematic sectional view of a further embodiment of apparatus according to the invention.

FIG. 4 is a schematic sectional view of yet another embodiment of apparatus according to the invention;

FIG. 5 is a schematic sectional view of yet a further embodiment of apparatus according to the invention;

FIG. 6 is a schematic sectional view of a further embodiment of apparatus according to the invention;

FIG. 7 is a schematic sectional view of a further embodiment of apparatus according to the invention;

FIG. 8 is a perspective view of an electroless plating assembly utilising the present invention;

FIG. 9 is a perspective view to an enlarged scale of part of the electroless plating assembly shown in FIG. 8;

FIG. 10 is a perspective view on yet a further enlarged scale of a basket forming part of the electroless plating assembly shown in FIGS. 8 and 9; and

FIG. 11 is a perspective view on a further enlarged scale of a manifold assembly with internal detail shown, forming part of the plating assembly illustrated in FIGS. 8 to 10.

### DETAILED DESCRIPTION OF THE DRAWINGS

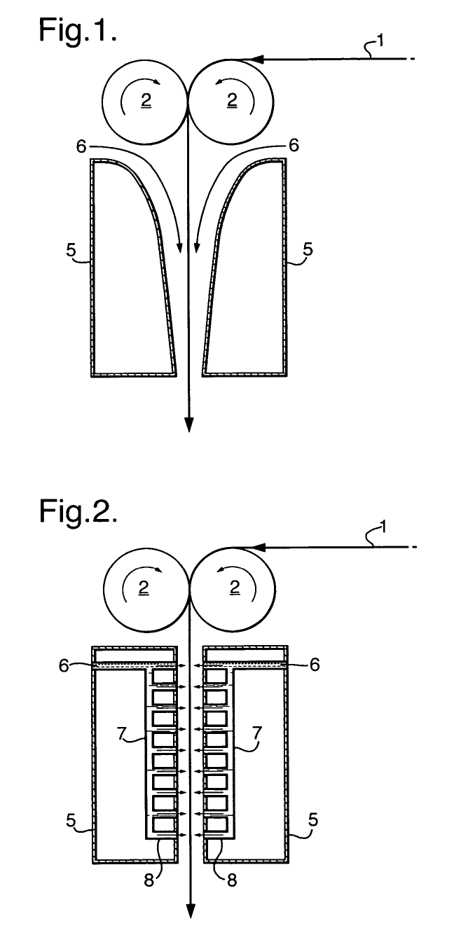

FIG. 1 shows schematically one embodiment of an apparatus according to the invention. A continuous web of flexible planar material 1 is drawn between a pair of driven pinch rollers 2 mounted at or near the top of a tank (not shown) and exits the rollers in a downward direction. The material enters and passes through an elongate tapering slot defined by a pair of fluid guides 5. A liquid 6 is fed into the gap between the guides on both sides of the material, constituting a flow of fluid to the material, and applies a drag force on the material 1 and prevents the material from touching the guides. The drag force induces a tension in the material 1 which ensures that the material does not buckle or fold whilst passing through the arrangement.

FIG. 2 shows a further embodiment of the invention that is generally similar to the FIG. 1 arrangement but wherein the liquid 6 is fed to the material 1 by being passed through a respective manifold 7 within each guide 5. The liquid enters the manifolds through entrance points and is fed via the manifolds to horizontal exit channels 8. This allows the fluid to form layers between the guides and the web across the whole surface of the guides. The liquid adheres to the material and applies a drag force on the material because of the action of gravity.

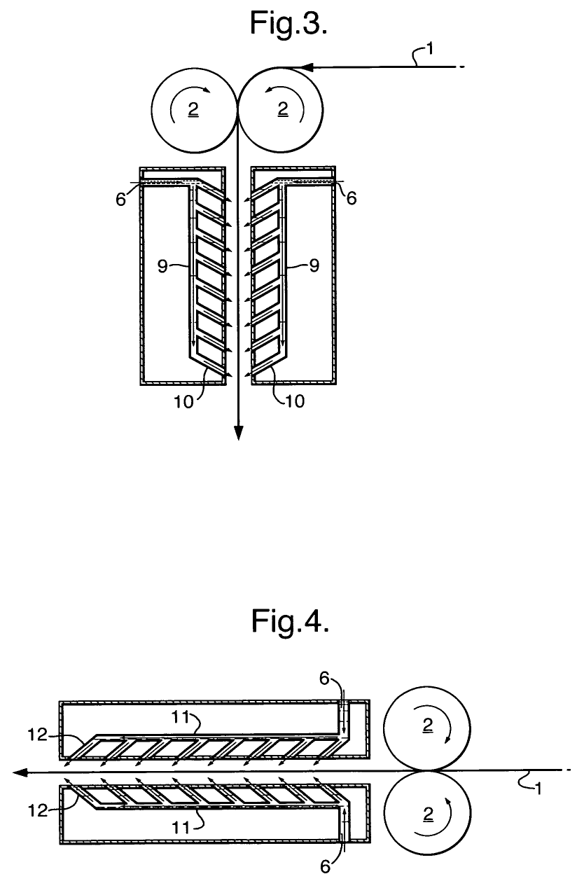

FIG. 3 shows a further embodiment of the invention that is generally similar to that shown in FIG. 2, but wherein each guide comprises a manifold or manifold assembly 9 with downwardly inclined exit channels 10. In the arrangement a component of the velocity of the liquid 6 is in the downwards direction and this increases the drag force applied to the material in the downwards direction, which in this case is the desired direction of motion of the material.

FIG. 4 shows an arrangement similar to that shown in FIG. 3, but with guides defining a horizontal guide slot. There is no gravitational force inducing a drag force on the material 1 in a direction away from the rollers 2. The fluid leaves the exit holes with a component of horizontal motion, in the direction of motion of the material 1. Thus, all of the drag force comes from the impingement of the fluid at an inclination to the material.

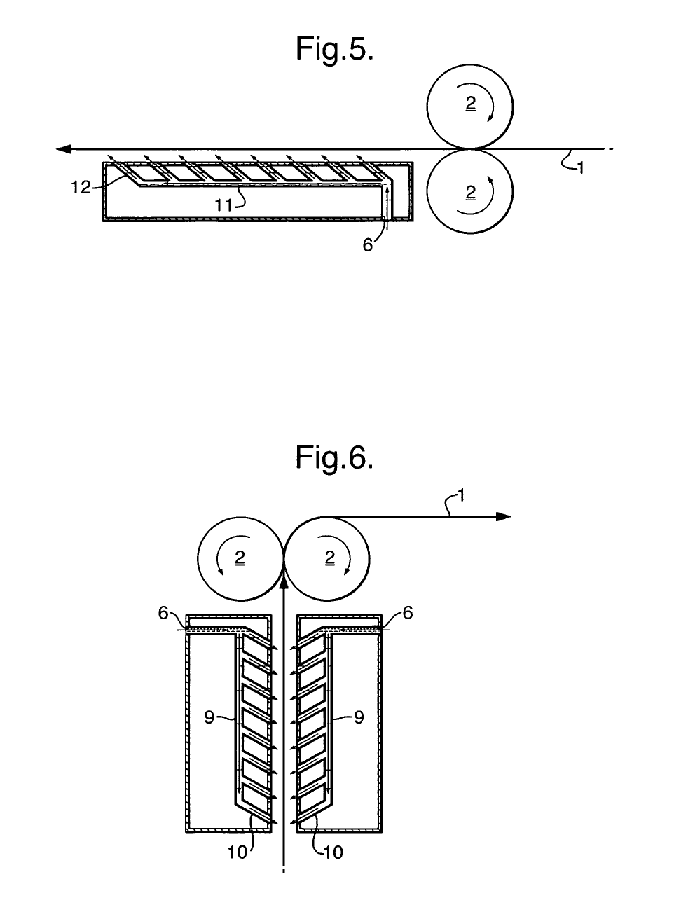

FIG. 5 shows an arrangement similar to that shown in FIG. 4, but with the fluid 6 applied to only the underside of the material 1. As in FIG. 4 the drag force is induced by the horizontal component of the momentum of the impinging fluid 6. The vertical component of the momentum is counter-balanced by the gravitational force acting on the material 1.

FIG. 6 shows an arrangement similar to that shown in FIG. 3, but wherein the material is moving in the opposite direction. In this case the drag force of the liquid opposes the motion of the material and provides an even tension on the material so that it may be more easily tracked and controlled in its motion through the rollers 2.

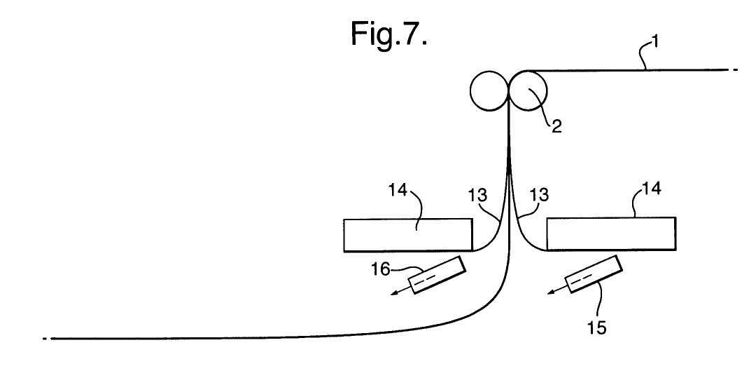

FIG. 7 illustrates a further embodiment of the invention. Web 1 is passed between two pinch rollers 2 in order to provide locomotion into a bath containing fluid. Immediately downstream of the rollers the web passes between two sets of wire guides 13 which provide a low-friction guide due to the minimal contact area of the wires with the web. The wire guides terminate in two mounting blocks 14 at the top of the tank.

Below the level of the mounting blocks and within the tank, two sets of water jets 15 and 16 spray fluid onto the web. The fluid jets serve two purposes:
1. They provide a means for recirculating and continually mixing the fluid.
2. They provide a fluid force on the web which in turn provides a locomotive force which continually drags the web into the bath.

In this configuration the two sets of fluid jets 15 and 16 can be used to select the direction that the web first travels in when it enters the bath. This is then used to control the way in which the web arranges itself as more web is fed into the tank. This is necessary because there are no rollers or other tensioning means within the bath.

The fluid jet 15 shown on the right hand side of the web is mainly responsible for selecting the direction that the web first bends into as it enters the tank. The fluid jet 16 on the left hand side of the web has a horizontal component to the direction of flow of the liquid. This provides a locomotive force which causes the web to traverse across the top of the bath of solution (not shown).

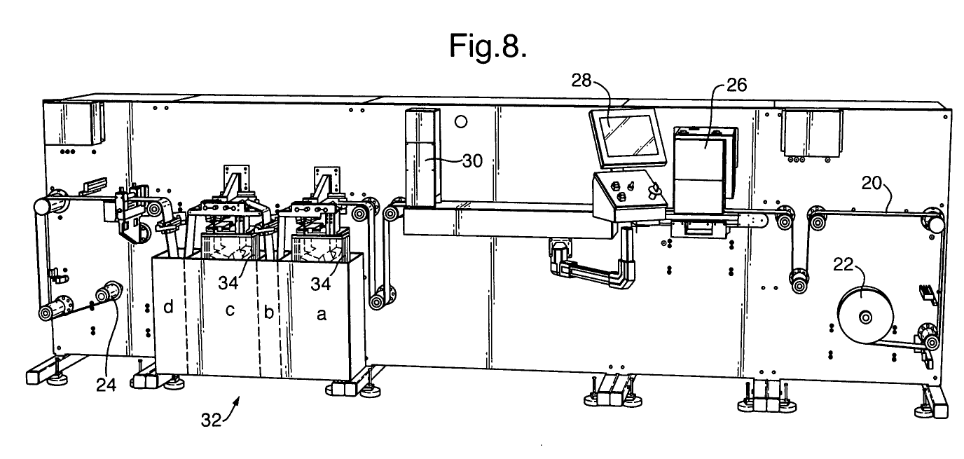

An embodiment of an electroless plating assembly which utilises the present invention is illustrated in FIGS. 8 to 11. As shown in FIG. 8, a web of flexible polyester 20 is conveyed from a supply reel 22 at one end of the assembly, to a take-up reel 24 at the other end. The web 20 is initially conveyed to an inkjet printer 26 with an associated computer 28. The printer 26 forms a pattern of palladium acetate solution on the web 20. The web 20 is then conveyed to an ultraviolet (UV) curing station 30 where the pattern applied of palladium acetate solution is fixed onto the web 20. Thereafter the web 20 is conveyed to a bath 32 divided internally into four chambers 32a-d. The first chamber 32a, which utilises apparatus according to the present invention, contains a solution of dimethylamineborane (DMAB) which reduces the palladium acetate to palladium which is catalytically active. The web is then washed in a bath of water in chamber 32b and then enters the third chamber 32c, which also utilises a fluid apparatus according to the present invention, which contains an electroless copper plating solution. This is followed by another water bath in chamber 32d. The web is then fed to the take-up reel 24 after suitable downstream processing.

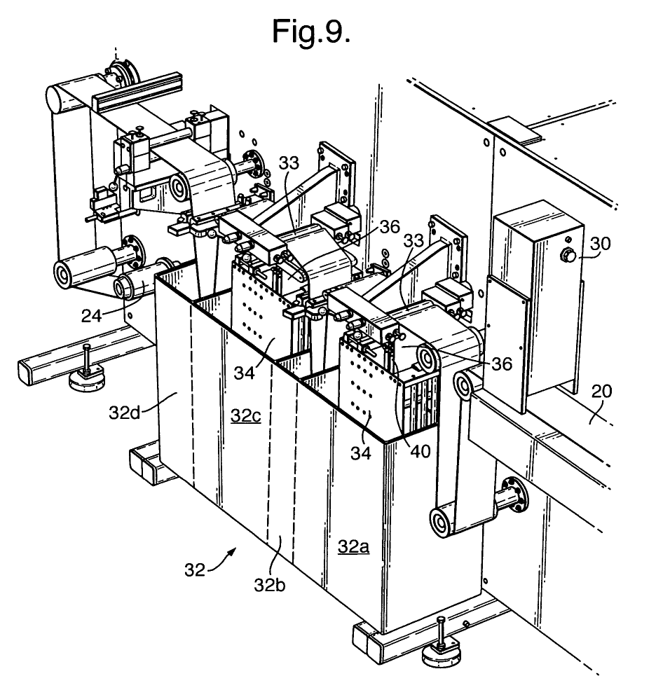

FIG. 9 shows in more detail the bath 32 of the apparatus shown in FIG. 8. It can be seen that the web is fed into the first chamber 32a using apparatus in accordance with the invention, by passing the web 20 past a pair of 2.54 mm driven rollers 33 (only one shown) which constitute the first contacting point, between a pair of fluid guides 36 and into a basket 34 measuring 300 mm×600 mm×155 mm. In chamber 32a the web follows a serpentine path in a tensionless state, as shown in WO 2006/100467. A similar arrangement is used in the third chamber 32c. The open baskets allow the tensionless web to be lifted out of the bath when it is desired to change the fluids in the bath. The web is under tension as it passes through water baths in chambers 32b,d, passing over a respective lower passive roller (not shown) at the bottom of each of these chambers.

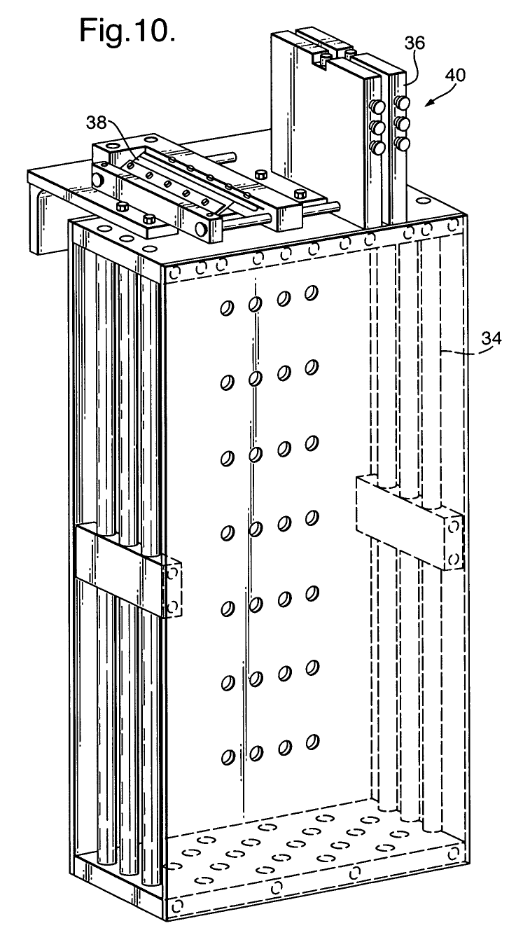

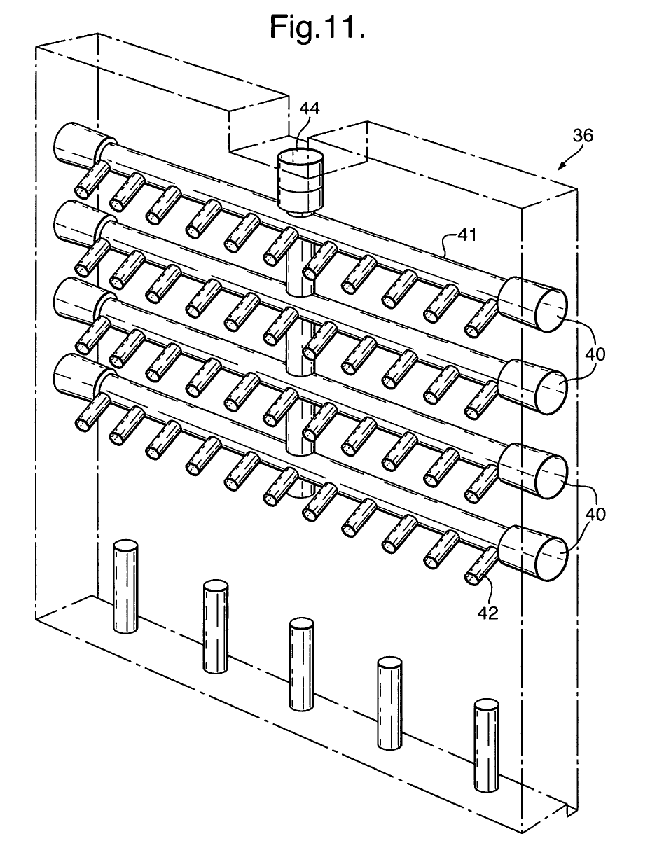

FIG. 10 shows a basket 34 removed from the bath. The basket has two opposed fluid web guides 36 comprising a pair of manifold assemblies generally as described in FIG. 3 and as shown in more detail in FIG. 11, which provides the entry point into the basket. A pair of driven rollers (not shown) directs the web into the gap or slot between the guides 36. As shown in FIG. 11, each manifold assembly has a plurality of side inlet holes 40 to receive a fluid supply. Each inlet 40 feeds to a respective manifold 41 which in turn feeds to a plurality of open ended channels 42. The channels each have a diameter of 2 mm and are downwardly inclined at approximately 30° below horizontal. A vertical bore 44 passes through the centre of the manifolds 41. A slight tapering of the web guide can be seen, so that when brought together with another such web guide the gap between the web guides is greater at the top than at the bottom. All but one of the inlet holes are plugged. When immersed in a bath a respective hose (not shown) is connected to each unplugged side inlet hole to provide fluid for the web guides.

Two Ocean Runner 6500 marine aquarium pumps (not shown) (from Aquamedic—Ocean Runner 6500 is a trade mark) are associated with each of chambers 32a and 32c (one pump per manifold assembly), with the pumps being arranged to feed liquid from a chamber via a respective hose (not shown) into one inlet hole 40 of each manifold assembly. The fluid passes through the manifold assemblies and is directed onto the web 20. The fluid then re-enters the chamber.

The fluid exiting from channels 42 applies a drag force on the web, ensuring that no buckling occurs. After exiting the guide the web is tensionless and follows a serpentine path (not shown) in the basket. The web exits the basket 34 via a squeegee slit formed by two rubber blades 38, constituting a second contacting point. The slit 38 has the dual function of wiping off any excess fluid on the web and inducing mild tension in the web with respect to another pair of driven rollers (not shown) above the slit 38.

### EXAMPLES

### Example 1

A test rig having an arrangement similar to that shown schematically in FIG. 1 was constructed, with a water bath containing a basket placed below.

A pair of 25.4 mm diameter pinch rollers 2 were used to translate a web 1 of 100 microns thick and 152 mm wide PET film (Melinex 339 from DuPont Teijin Films) from a horizontal plane downwards into a polypropylene basket which was immersed in a water bath. The basket was 155 mm wide in order to closely accommodate the 152 mm wide web to ensure any folding of the web was confined to only two dimensions in the basket. Perpendicular to the plane of the web the basket measured 300 mm×300 mm. In order to guide the web into the basket the material was passed between two 200 mm long polypropylene guides 5 with a tapered gap between them. At the entrance to the basket these guides were separated by 5 mm. At the top of the guides they were separated by around 50 mm.

When the web was fed through the rollers at speeds of between 1 cm/s and 25 cm/s it was noticed that the web would quickly adhere to one or other of the guides and would then cease to feed into the immersed basket.

This problem was cured when water 6 from a garden hose was allowed to flow at a rate of approximately 10 litres per minute over each of the guides 5. This gave a flow of water which separated the web from each of the guides and helped to drag the web into the basket as it was fed in by the rollers.

### Example 2

Using the apparatus of FIGS. 8 to 11, a web 20 of Melinex 339 polyester (from DuPont Teijin Films) 100 microns thick and 50 mm wide had printed on one surface thereof a palladium acetate activator solution at the printer station 26. The solution was applied thereto in a pattern on only selected areas of the surface by inkjet printing, generally as described in WO 2004/068389. In particular, the following activator solution was used:

| | % (by weight) |
|---|---|
| Palladium acetate | 2.0 |
| Irgacure 1700 | 3.25 |
| Irgacure 819 | 1.25 |
| DPGDA | 30.5 |
| DPHA | 3.0 |
| Actilane 505 | 10.0 |
| Diacetone alcohol | 47.5 |
| PVP K30 | 2.5 |
| Viscosity, cPs (25° C.) | 17.6 |

Palladium acetate is present as an activator. Igracure 1700 and Igracure 819 are UV photo-initiators supplied by Ciba Speciality Chemicals, Macclesfield, UK—Irgacure is a Trade Mark. DPGDA is dipropylene glycol diacrylate, a UV-curable reactive diluent monomer supplied by UCB, Dragenbos, Belgium. DPHA is dipentaerythritol hexacrylate, a UV-curable hexafunctional monomer, supplied by UCB, Dragenbos, Belgium. Actilane 505 is a UV-curable reactive tetrafunctional polyester acrylate oligomer supplied by Akzo Nobel UV Resins, Manchester, UK. The monomers and oligomers are in liquid form. Diacetone alcohol is a solvent for the palladium acetate. PVP K30 is a grade of polyvinyl pyrrolidinone supplied by ISP, Tadworth, UK.

PVP constitutes a water soluble chemical functionality. The monomers and oligomers, Actilane 505, DPHA and DPGDA, react to form a polymer that constitutes a water insoluble chemical functionality.

This fluid was printed with a XJ500/180 print head (available from Xaar of Cambridge, England) at 180×250 dpi.

At UV curing station 30 the samples were cured under a Fusion 500 Watt H-bulb, resulting in formation of an activator layer.

The pre-printed web 20 was fed to the tank 32, and was passed through chambers 32a to 32d in sequence, as described above at a speed of 0.25 m/s. Fluid was pumped from chambers 32a, c to their respective fluid guides 36 at a rate of 40 l/min (20 l/min for each hose).

The third chamber 32c is substantially filled with an electroless copper plating solution comprising Enplate 872 A, B and C reagents (Enplate is a Trade Mark) which are available from Enthone Ltd of Woking, UK and are in common use as component solutions for electroless copper plating. In particular, the electroless copper plating solution has the following composition:

| | % (by weight) |
|---|---|
| Enplate 872 A | 10.713 |
| Enplate 872 B | 10.713 |
| Enplate 872 C | 3.571 |
| water | balance to 100% |

Enplate 872A contains copper sulphate. Enplate 872B contains a cyanide complexing agent (Quadrol) and formaldehyde. Enplate 872 C contains sodium hydroxide and potassium cyanide. The solution was heated to 45° C.

The length of web immersed in the chamber 32c was 15 m, giving a residence time of one minute.

This treatment produced a conductive copper film on the regions of the web surface to which the catalytically active palladium had been applied.

Experiments were performed with the web passing through the apparatus at different speeds, ranging from 0.01 m/s to 0.6 m/s. No tangling of the web occurred at the web guides.

1. A method of handling a length of flexible planar material, comprising conveying the material past a first contacting point, and applying a flow of fluid to the material thereby applying a drag force on the material which induces a tensile force in the material with respect to the contacting point.

2. A method according to claim 1, wherein the first contacting point is a roller.

3. A method according to claim 2, wherein the first contacting point is a pair of rollers, at least one of which is driven.

4. A method according to claim 1, wherein the material is conveyed past a second contacting point.

5. A method according to claim 1, wherein fluid is applied downstream of the first contacting point.

6. A method according to claim 1, wherein the fluid is a liquid.

7. A method according to claim 1, wherein the fluid is directed to impact the material with a velocity having a component directed away from the first contacting point.

8. A method according to claim 1, wherein fluid is applied to both sides of the material.

9. A method according to claim 1, wherein the fluid is applied in a plurality of channels or jets.

10. A method according to claim 1, wherein the material passes through a pair of opposed manifold assemblies constituting fluid guides defining therebetween an elongate slot or gap.

11. A method according to claim 1, wherein the material passes through a fluid bath.

12. A method according to claim 11, wherein the fluid applied to the material is the same fluid as the bath contents.

13. A method according to claim 1, wherein an electrically conductive metal layer is formed on the flexible planar material.

14. Apparatus for handling a length of flexible planar material, comprising a first contacting point, means for conveying the material past the first contacting point, and means for applying a flow of fluid to the material such that, in use, fluid applied to the material applies a drag force on the material which induces a tensile force in the material with respect to the contacting point.

15. Apparatus according to claim 14, wherein the first contacting point is a roller.

16. Apparatus according to claim 15, wherein the first contacting point is a pair of rollers, at least one of which is driven.

17. Apparatus according to 14, which comprises a second contacting point and means for conveying the material past the second contacting point.

18. Apparatus according to claim 14, wherein, in use, fluid is applied downstream of the first contacting point.

19. Apparatus according to claim 14 wherein, in use, the fluid is directed to impact the material with a velocity having a component directed away from the contacting point.

20. Apparatus according to claim 14 wherein, in use, fluid is applied to both sides of the material.

21. Apparatus according to claim 14 wherein, in use, the fluid is applied in a plurality of channels or jets.

22. Apparatus according to claim 14 wherein, in use, the material passes through a pair of opposed manifold assemblies constituting fluid guides defining therebetween an elongate slot or gap.

23. Apparatus according to claim 14, which comprises a fluid bath and wherein, in use, the material passes through the fluid bath.

24. Apparatus according to claim 23, wherein the fluid applied to the material is the same fluid as the bath contents.

25. Apparatus according to claim 14 comprising means for forming an electrically conductive metal layer on the flexible planar material.
